(19) United States
(12) Patent Application Publication
(10) Pub. No.: US 2026/0013075 A1
(43) Pub. Date: Jan. 8, 2026

(54) ELECTRONIC PACKAGES HAVING IMMERSION COOLING

(71) Applicant: Toyota Motor Engineering & Manufacturing North America, Inc., Plano, TX (US)

(72) Inventors: Feng Zhou, Ann Arbor, MI (US); Tianzhu Fan, Houston, TX (US); Shailesh Joshi, Ann Arbor, MI (US); Danny J. Lohan, West Bloomfield, MI (US); Ercan Mehmet Dede, Ann Arbor, MI (US)

(73) Assignee: Toyota Motor Engineering & Manufacturing North America, Inc., Plano, TX (US)

(21) Appl. No.: 18/763,338

(22) Filed: Jul. 3, 2024

(51) Int. Cl. H05K 7/20; H02M 3/00

(52) U.S. Cl. CPC H05K 7/20272; H02M 3/003; H05K 7/20236; H05K 7/20927

(57) ABSTRACT

An electronics package includes a manifold housing defining an enclosure and including an inlet port fluidly coupled to an inlet manifold, an outlet port fluidly coupled to an outlet manifold, a first inlet, a second inlet, a third inlet, and a fourth inlet, each fluidly coupled to the inlet manifold and the enclosure, and a first outlet, a second outlet, a third outlet, and a fourth outlet, each fluidly coupled to the outlet manifold and the enclosure. The electronics package also includes a first circuit board coupled to the manifold housing, and a second circuit board coupled to the manifold housing such that the second circuit board is offset from the first circuit board by a first gap. The electronics package further includes a third circuit board coupled to the manifold housing such that the third circuit board is offset from the second circuit board by a second gap.

### BACKGROUND

Electronic devices may produce significant waste heat that should be removed to ensure that they operate within maximum temperature thresholds. For example, power electronic devices, such as those operating as switches in inverter and converter circuits, may operate at significant power. Heat removal technologies include heat sink fins, single-phase liquid cooling, and two-phase liquid cooling, for example. However, such existing technologies may not be suitable for high-power applications where many components may need cooling at multiple surfaces.

According, alternative electronics packages having improved cooling may be desired.

### BRIEF SUMMARY

In one embodiment, an electronics package includes a manifold housing defining an enclosure. The manifold housing includes an inlet port fluidly coupled to an inlet manifold, an outlet port fluidly coupled to an outlet manifold, a first inlet, a second inlet, a third inlet, and a fourth inlet, each fluidly coupled to the inlet manifold and the enclosure, and a first outlet, a second outlet, a third outlet, and a fourth outlet, each fluidly coupled to the outlet manifold and the enclosure. The electronics package also includes a first circuit board coupled to the manifold housing. The electronics package also includes a second circuit board coupled to the manifold housing such that the second circuit board is offset from the first circuit board by a first gap. The electronics package further includes a third circuit board coupled to the manifold housing such that the third circuit board is offset from the second circuit board by a second gap. The electronics package also includes a first plate coupled to a first surface of the manifold housing. The electronics package further includes a second plate coupled to a second surface of the manifold housing.

In another embodiment, a composite DC-DC converter includes a manifold housing defining an enclosure. The manifold housing includes an inlet port fluidly coupled to an inlet manifold, an outlet port fluidly coupled to an outlet manifold, a magnetics inlet, a first power inlet, a second power inlet, and a control inlet, each fluidly coupled to the inlet manifold and the enclosure, and a magnetics outlet, a first power outlet, a second power outlet, and a control outlet, each fluidly coupled to the outlet manifold and the enclosure. The composite DC-DC converter also includes a magnetics circuit board coupled to the manifold housing and includes planar windings and a plurality of magnetic cores. The composite DC-DC converter further includes a power circuit board coupled to the manifold housing such that the power circuit board is offset from the magnetics circuit board by a first gap. The power circuit board includes a plurality of embedded power electronic devices. The composite DC-DC converter also includes a control circuit board coupled to the manifold housing such that the control circuit board is offset from the power circuit board by a second gap, the control circuit board includes electronic devices capable of controlling the plurality of embedded power electronic devices. The composite DC-DC converter also includes a first plate coupled to a first surface of the manifold housing. The composite DC-DC converter further includes a second plate coupled to a second surface of the manifold housing.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a perspective view of an example electronics package according to one or more embodiments described and illustrated herein.

FIG. 2 illustrates a cross-sectional view of an example electronics package according to one or more embodiments described and illustrated herein.

FIG. 3 illustrates a bottom view of the example electronics package of FIG. 2 with a second plate and a control circuit board removed according to one or more embodiments described and illustrated herein.

FIG. 4 illustrates a bottom view of the example electronics package of FIG. 2 with the second plate removed according to one or more embodiments described and illustrated herein.

FIG. 5 illustrates another cross-sectional view of the electronics package of FIG. 2 according to one or more embodiments described and illustrated herein.

FIG. 6 illustrates a cross-sectional view of another electronics package according to one or more embodiments described and illustrated herein.

FIG. 7 illustrates a cross-sectional view of another electronics package according to one or more embodiments described and illustrated herein.

FIG. 8 illustrates a cross-sectional view of another electronics package according to one or more embodiments described and illustrated herein.

### DETAILED DESCRIPTION

Embodiments of the present disclosure are directed to electronics packages, such as DC-DC converters, inverters, rectifiers, and the like, that utilize a manifold housing for direct immersion within a dielectric cooling fluid. Circuit boards are disposed within an enclosure, with the circuit boards defining cooling fluid flow paths. Gaps between adjacent circuit boards and first and second plates can be adapted to provide different cooling fluid velocities depending on the heat density of the cooled electronic components. Different heat transfer enhancement technologies can be applied to a power circuit board having embedded power electronic devices to further enhance heat transfer to the cooling fluid.

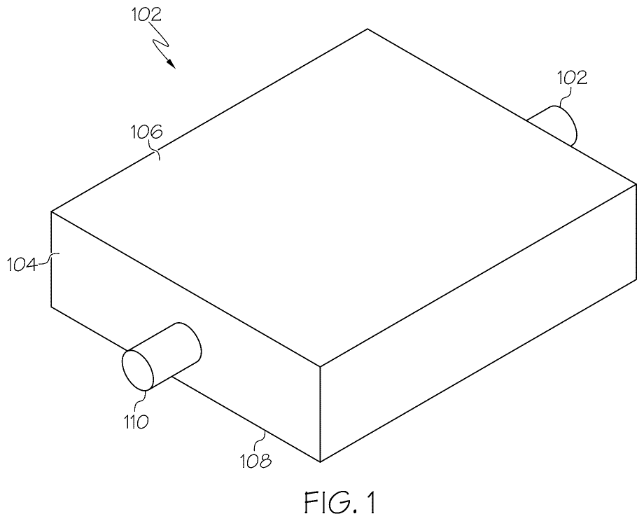

Referring now to FIG. 1, an example electronics package 102 is illustrated. The electronics package 102 can be any electrical circuit, such as a DC-DC converter (e.g., a composite DC-DC converter), an inverter, a rectifier, a switch, among others. As described in more detail below, the electronics package 102 combines both the electronic devices of the desired circuit as well as immersion cooling functionality in a single package. The electronics package 102 has a housing that is defined by a manifold housing 104, a first plate 106 (e.g., a top plate) and a second plate 108 (e.g., a bottom plate). The manifold housing 104, which may be made of molded or three-dimensionally printed plastic or other electrically insulative material, provides an inlet port 110 and an outlet port 112. In some embodiments, more than one inlet port 110 and/or more than one outlet 112 is provided. Although not shown in FIG. 1, fluid lines couple the inlet port 110 and the outlet port 112 to other system components, such as a pump, a heat exchanger, and a fluid reservoir. It is also noted that voltage input and output terminals of the electronics package 102 are also not shown in FIG. 1.

A cooling fluid enters an enclosure defined by the manifold housing 104, the first plate 106 and the second plate 108 by way of the inlet port 110. The cooling fluid is a dielectric cooling fluid such that the electronic components within the enclosure may be directly immersed in the cooling fluid without shorting. Non-limiting dielectric cooling fluid includes hydrocarbons and fluorocarbons, such as dielectric coolants sold by Engineered Fluids of Tyler TX.

The cooling fluid is distributed into the enclosure by the manifold housing 104 where it then takes several flow paths over multiple surfaces of various electronic components. Heat generated by the electronic components is directly transferred to the cooling fluid as it flows within the enclosure. The cooling fluid then leaves the enclosure thought the outlet port 112, where it may be routed to a heat exchanger to be cooled and then re-introduced to the enclosure in a closed-loop system. The cooling fluid removes heat generated by the electronic components so that they operate within maximum operating temperatures.

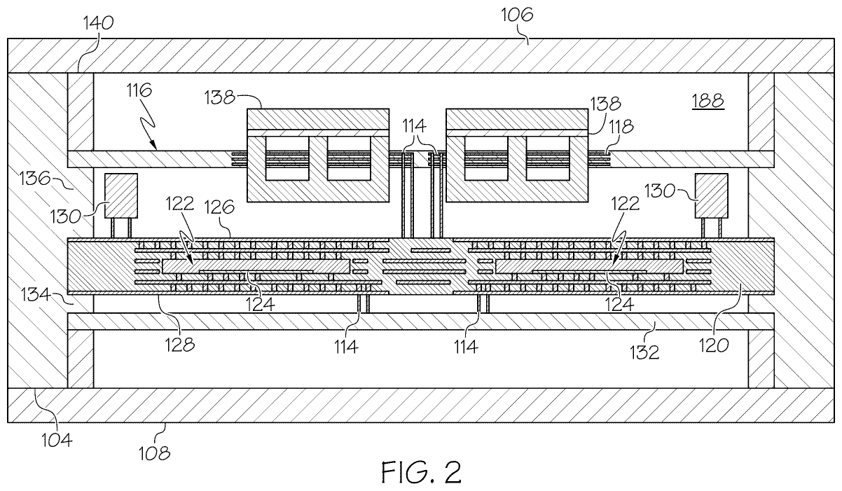

FIG. 2 is a cross-sectional view of an example electronics package 102 showing various internal components within the enclosure 188. In the illustrated embodiment, the enclosure 188 maintains three circuit boards: a first circuit board configured as a magnetics circuit board 116, a second circuit board configured as a power circuit board 120 and a third circuit board configured as a control circuit board 132. It should be understood that the three circuit boards may be arranged in different orders, or have different functions than the magnetics circuit board 116, the power circuit board 120 and the control circuit board 132 depending on the application for which the electronics package 102 is intended for. The illustrated electronics package 102 of FIG. 2 is a composite DC-DC converter capable of receiving a DC input voltage and producing various DC output voltages, and thus may include power electronic devices 124 capable of defining a buck converter, a boost converter, a buck-boost converter, and/or the like. As a non-limiting example, the electronics package 102 may be a composite DC-DC converter of an electric vehicle that boosts the battery voltage of the vehicle battery to a DC bus voltage in an electric vehicle traction drive system. Such composite DC-DC converters may operate at a high power (e.g., 125-kW) and thus generate significant heat that should be removed to ensure that all of the electronic components operate within their maximum operating temperature thresholds.

The magnetics circuit board may be a printed circuit board fabricated from a dielectric material, such as FR-4, for example. The magnetics circuit board 116 provides inductors and/or transformers for the desired circuit, such as a composite DC-DC converter, in the form of planar windings 118 and magnetic cores 138. As the inductors and/or transformers store significant energy during operation, they generate heat that should be removed by the cooling fluid, as described in more detail below.

Any number of inductors and/or transformers may be provided by the magnetics circuit board 116. As a non-limiting example, the magnetics circuit board 116 may include eight inductors and one transformer by the planar windings 118 and the magnetic cores 138.

As described in more detail below, an interior perimeter wall of the manifold housing 104 has a plurality of interlaced ledges for the circuit boards. The magnetics circuit board 116 is supported by ledges 136. The magnetics circuit board 116 may be secured to the ledges 136 by fasteners, such as screws, as a non-limiting example.

A gasket 140 is provided around an outer perimeter of the magnetics circuit board 116 and an interior perimeter of the manifold housing 104. The first plate 106 is secured to the manifold housing 104 such that the gasket 140 compresses and forms a seal to keep the cooling fluid within the enclosure 188. The gasket 140 may be made of any suitable material, such as rubber, for example. The first plate 106 may be made of a thermally conductive material, such as copper or aluminum, for example. The first plate 106 may be secured to the manifold housing 104 by any suitable means, such as by fasteners.

The power circuit board 120 is disposed within the enclosure such that it is offset from the magnetics circuit board 116 by a first gap G1. The power circuit board 120 provides the power electronic devices 124 that define the desired circuit, such as a composite DC-DC converter. The power electronic devices 124 may be switching devices, such as insulated-gate bi-polar transistors (IGBT) or power metal-oxide-semiconductor field-effect transistors (“power MOSFET”). In the illustrated embodiment, the power electronic devices 124 are completely embedded within the power circuit board 120, which may be made of FR-4, ceramic, glass, and artificial diamond, for example. In other embodiments, one or more of the power electronic devices 124 may be mounted on a surface of the power circuit board 120. Any number of power electronic devices 124 may be provided depending on the intended application. In the embodiment illustrated by FIG. 2, each power electronic device 124 is mounted on an electrically and thermally conductive substrate 122. The substrate 122 has a recess in which the power electronic device 124 sits. The substrate 122 may comprise copper such that conductive traces and vias can be electrically connected to bottom electrodes of the power electronic device 124. In some embodiments, the substrate 122 has a graphite core (not shown) that is surrounded by a metal layer, as described in U.S. patent application Ser. No. 17/874,462, titled Power Electronics Assemblies Having Embedded Power Electronics Devices and filed on Jul. 27, 2022, which is hereby incorporated by reference in its entirety.

In some embodiments, the gap G1 is such that it can accommodate additional electronic components. In the illustrated embodiment, power capacitors 130, which also generate significant heat during charging and/or discharging, should be cooled. The capacitors 130 are mounted to a surface of the power circuit board 120 such that they are within the first gap G1 between the power circuit board 120 and the magnetics circuit board 116. Cooling liquid passing by the capacitors 130 will remove their heat thereby ensuring that they operate within their maximum operating temperature thresholds.

Like the magnetics circuit board 116, the power circuit board 120 may be secured to the ledges 136 of the manifold housing 104. The components of the power circuit board 120 are electrically coupled to the inductors of the magnetic power circuit board 120 by a plurality of vertical connectors 114, for example.

The control circuit board 132, which may also be a printed circuit board, includes active and passive electronic components (not shown) for controlling the power electronic devices 124 within the power circuit board 120. Such electronic components may include gate-drive integrated circuits, resistors, inductors, capacitors, diodes, transistors, and the like.

The control circuit board 132 is mounted to the manifold housing 104 at ledges 134 such that it is offset from the power electronic devices 124 by a second gap G2. The control circuit board 132 is electrically coupled to the power circuit board 120 by vertical connectors 114. For example, gate drive signals generated by the control circuit board 132 pass through the vertical connectors 114 to the gates of the various power electronic devices 124 to switch them on and off as needed.

Another gasket 140 is also provided around an outer perimeter of the control circuit board 132 and an inner perimeter wall of the manifold housing 104. The second plate 108 is secured to the manifold housing 104 such that the gasket 140 compresses and forms a seal to keep the cooling fluid within the enclosure 188. The second plate 108 may be made of a thermally conductive material, such as copper or aluminum, for example. The second plate 108 may be secured to the manifold housing 104 by any suitable means, such as by fasteners.

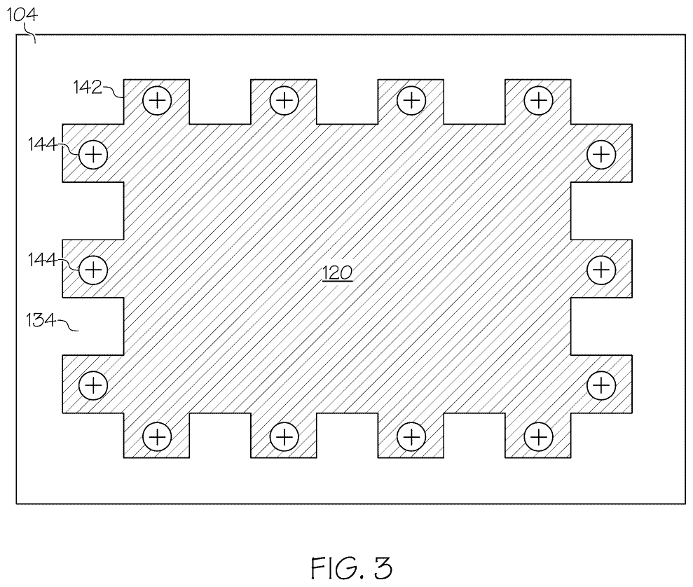

Referring now to FIG. 3, a bottom view of the electronics package 102 with the second plate 108 and the control circuit board 132 removed is provided, thereby revealing the power circuit board 120 and the manifold housing 104. The power circuit board 120 has a plurality of flanges 142 around its perimeter. These flanges 142 rest on ledges 136. The flanges 142 are secured by the ledges 136 by fasteners, such as screws, as a non-limiting example. Other means for securing the power circuit board 120 to the ledges 136 may also be utilized. Ledges 134, which are at a different height from ledges 136, are exposed to receive the control circuit board 132.

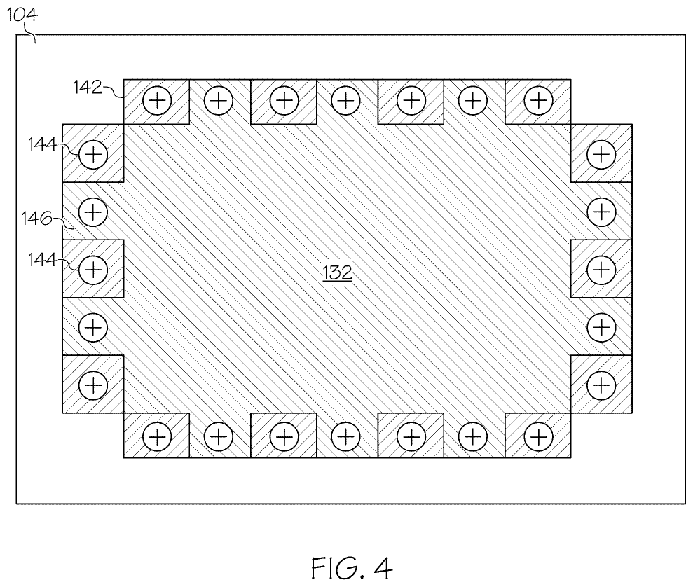

Referring now to FIG. 4, a bottom view of the electronics package with the second plate 108 removed is provided. FIG. 4 illustrates how the control circuit board 132 may be secured to the manifold housing 104. The example control circuit board 132 has a plurality of flanges 146 around its perimeter. The flanges 146 of the control circuit board 132 are vertically offset from the flanges 144 of the power circuit board 120. The flanges 146 of the control circuit board 132 sit on ledges 134 of the manifold housing 104, and may be secured by fasteners 192, such as screws. Other means for securing the control circuit board 132 to the ledges 134 may also be utilized.

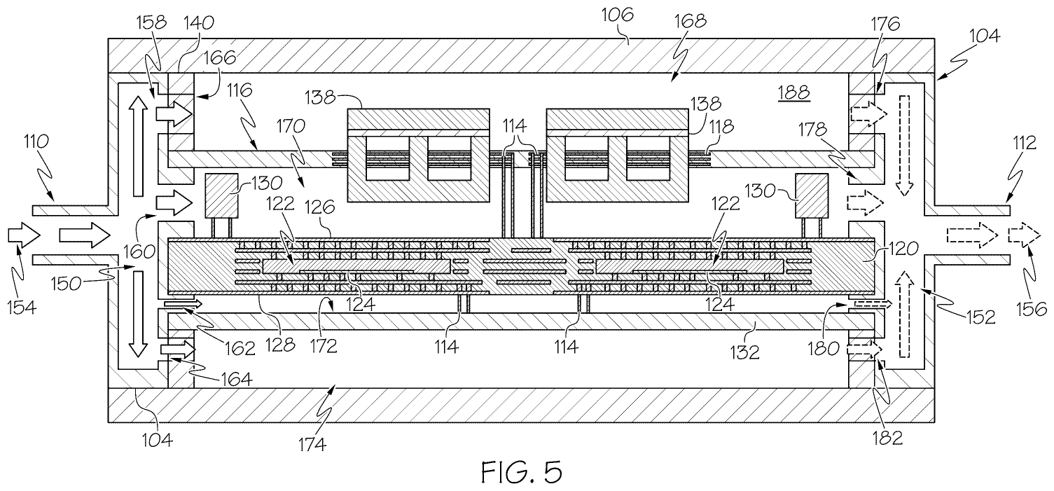

FIG. 5 illustrates another cross-sectional view of the example electronics package 102 that illustrates an inlet manifold 150 and an outlet manifold 152 within the manifold housing 104. The manifold housing 104 may be molded or three-dimensionally printed to include the features disclosed herein. The inlet manifold 150 is a chamber within a side wall of the manifold housing 104 that is fluidly coupled to the inlet port 110. The inlet manifold 150 therefore receives cooling fluid 154 from the inlet port 110. The inlet manifold 150 is also coupled to a plurality of inlets fluidly coupled to the enclosure 188. A first inlet is configured as a magnetics inlet 158 fluidly coupled to the enclosure 188 to introduce cooling fluid 154 into a magnetics fluid path 168 that is between the first plate 106 and the magnetics circuit board 116. A second inlet is configured as a first power inlet 160 fluidly coupled to the enclosure 188 to introduce cooling fluid 154 into a first power fluid path 170 that is between the magnetics circuit board 116 and the power circuit board 120. A third inlet is configured as a second power inlet 162 fluidly coupled to the enclosure 188 to introduce cooling fluid 154 into a second power fluid path 172 that is between the control circuit board 132 and the power circuit board 120. A fourth inlet is configured as a control inlet 164 fluidly coupled to the enclosure 188 to introduce cooling fluid 154 into a control fluid path 174 that is between the control circuit board 132 and the second plate 108.

Each of the inlets may be configured as circular nozzles and/or slots that are openings between the inlet manifold 150 and the enclosure 188 to allow cooling fluid 154 to pass from the inlet manifold 150 to the enclosure 188.

The outlet manifold 152 is a chamber within a side wall of the manifold housing 104 that is fluidly coupled to the outlet port 112. The outlet manifold 152 therefore receives warmed cooling fluid 156 from the various fluid paths within the enclosure 188. The outlet manifold 152 is also coupled to a plurality of outlets fluidly coupled to the enclosure 188. A first outlet is configured as a magnetics outlet 176 fluidly coupled to the enclosure 188 to receive warmed cooling fluid 156 from the magnetics fluid path 168. A second outlet is configured as a first power outlet 178 fluidly coupled to the enclosure 188 to receive warmed cooling fluid 156 from the first power fluid path 170. A third outlet is configured as a second power outlet 180 fluidly coupled to the enclosure 188 to receive warmed cooling fluid 156 from the second power fluid path 172. A fourth outlet is configured as a control outlet 182 fluidly coupled to the enclosure 188 to receive warmed cooling fluid 156 from the control fluid path 174.

Each of the outlets may be configured as circular openings and/or slot that provide openings between the enclosure 188 and the outlet manifold 152 to allow warmed cooling fluid 156 to pass from the enclosure 188 to the outlet manifold 152. The gaskets 140 include gasket openings 166 (e.g., holes, slots, etc.) that are aligned with the inlets and outlets to allow cooling fluid to pass to and from the various fluid paths within the enclosure.

Each fluid path allows cooling fluid 154 to pass over different components. The magnetics fluid path 168 cools the magnetic cores 138 and planar windings 118 of the magnetics circuit board 116. The first power fluid path 170 cools the magnetic cores 138 and planar windings 118 of the magnetics circuit board 116, as well as the power electronic devices 124 and the capacitors 130 of the power circuit board 120. The second power fluid path 172 cools the power electronic devices 124 of the power circuit board 120 as well as electronic components of the control circuit board 132.

The gaps between adjacent layers can be manipulated to provide a desired cooling fluid velocity. Components needing more cooling, such as the power electronic devices 124, benefit from a higher fluid velocity that provides more effective heat transfer and removal. Thus, the gaps can be tuned to produce desired cooling fluid volumetric flow rate on top of each component to dissipate desired heat load. Tuning the gap sizes to power dissipation has similar effect as to changing heat sink designs of conventional converters having indirect cooling. The size of the various gaps can be achieved by sizing the heights of the ledges of the interior perimeter wall of the manifold housing 104.

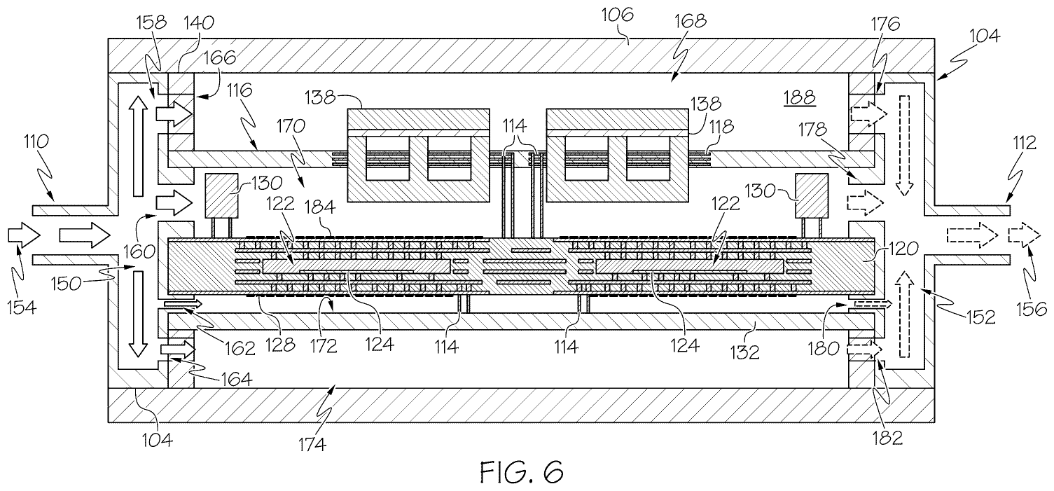

Because the embedded power electronic devices 124 generate the most heat, heat transfer enhancement technologies may be applied to the power circuit board 120 to further increase cooling performance. Referring now to FIG. 6, in some embodiments one or more surfaces of the power circuit board 120 are roughened to increase surface roughness. For example, a heat transfer pattern 184 may roughen the surfaces of the power circuit board 120. The heat transfer pattern 184 may be provided by laser etching, chemical etching, or other methods to enhance the heat transfer between coolant and the circuit board. The roughened surfaces of the power circuit board 120 provides an increase in surface area at which the cooling fluid 154 contacts the power circuit board 120.

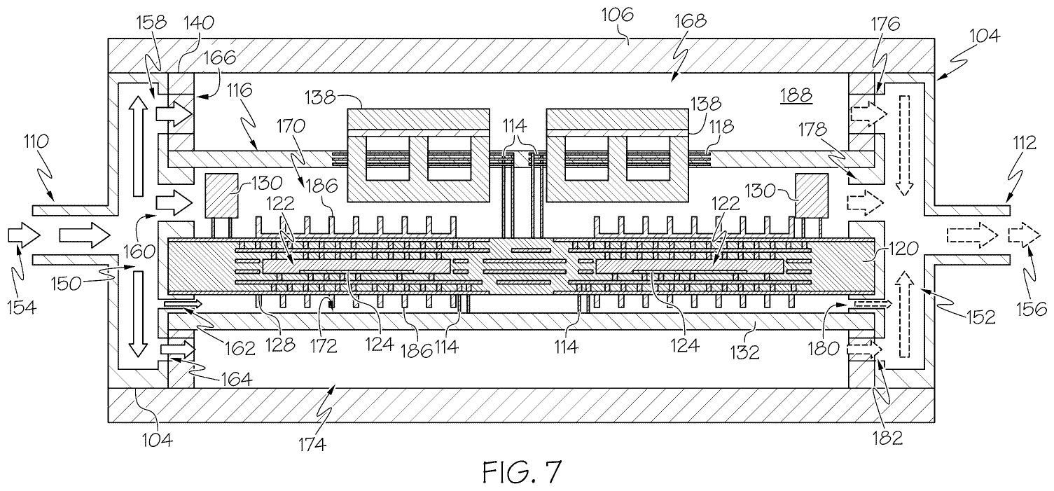

Heat sink fins 186 may also be provided on one or more surfaces of the power circuit board 120 to increase the surface area at which the cooling fluid 154 contacts the power circuit board 120, as shown in FIG. 7. The heat sink fins 186 can take on any arrangement and shape, and thus can be optimized to provide optimal heat transfer to the cooling fluid 154. In some embodiments, the power circuit board 120 includes both a roughened surface by a heat transfer pattern 184 and a heat sink fins 186.

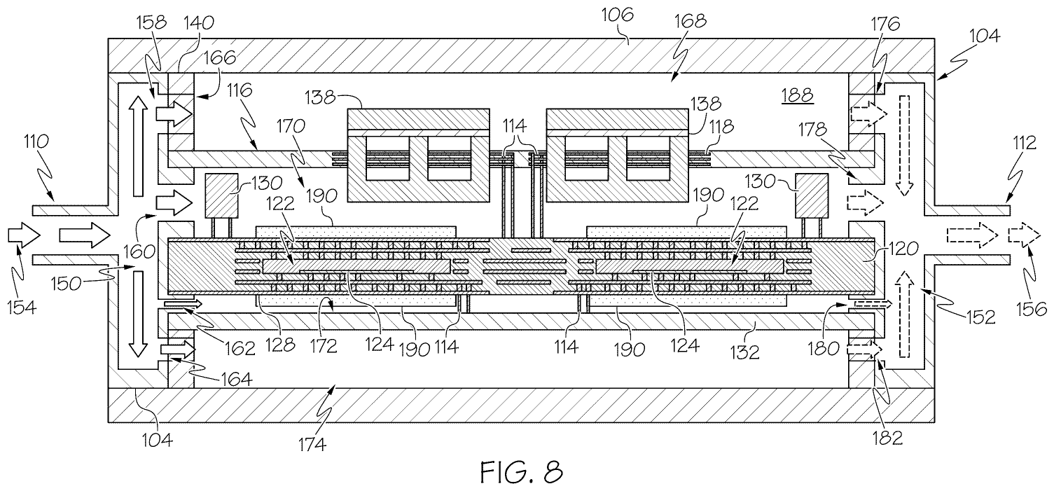

Referring to FIG. 8, porous structures 190 may be positioned above and/or below the power electronic devices 124 on surfaces of the power circuit board 120. These porous structures 190 provide additional heat transfer surface area for the cooling fluid 154. The porous structures 190 may be bonded to the surfaces of the power circuit board 120. In some embodiments, the porous structures 190 may be grown on the surfaces of the power circuit board 120 at the desired locations. As a non-limiting example, the porous structures 190 may be copper-inverse-opal structures having a network of pores through which the cooling fluid 154 flows.

For all of the additional heat transfer enhancement methods described above, the copper surfaces of the power circuit board 120 may be oxidized to make them rougher for enhanced boiling if two-phase immersion boiling is utilized.

It should now be understood that embodiments of the present disclosure are directed to electronics packages, such as DC-DC converters, inverters, rectifiers, and the like, that utilize a manifold housing for direct immersion within a dielectric cooling fluid. Circuit boards are disposed within an enclosure, with the circuit boards defining cooling fluid flow paths. Gaps between adjacent circuit boards and first and second plates can be adapted to provide different cooling fluid velocities depending on the heat density of the cooled electronic components. Different heat transfer enhancement technologies can be applied to a power circuit board having embedded power electronic devices to further enhance heat transfer to the cooling fluid.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

1. An electronics package comprising:
a manifold housing defining an enclosure and comprising:
an inlet port fluidly coupled to an inlet manifold;
an outlet port fluidly coupled to an outlet manifold;
a first inlet, a second inlet, a third inlet, and a fourth inlet, each fluidly coupled to the inlet manifold and the enclosure; and
a first outlet, a second outlet, a third outlet, and a fourth outlet, each fluidly coupled to the outlet manifold and the enclosure;
a first circuit board coupled to the manifold housing;
a second circuit board coupled to the manifold housing such that the second circuit board is offset from the first circuit board by a first gap;
a third circuit board coupled to the manifold housing such that the third circuit board is offset from the second circuit board by a second gap;
a first plate coupled to a first surface of the manifold housing; and
a second plate coupled to a second surface of the manifold housing.

2. The electronics package of claim 1, further comprising a first gasket disposed between the first plate and the first circuit board and a second gasket disposed between the second plate and the second circuit board, wherein each of the first gasket and the second gasket comprises an individual gasket opening at the first inlet, the second inlet, the third inlet, the fourth inlet, the first outlet, the second outlet, the third outlet, and the fourth outlet.

3. The electronics package of claim 1, wherein:
a first fluid path is between the first inlet and the first outlet and the first plate and the first circuit board;
a second fluid path is within the first gap between the second inlet and the second outlet;
a third fluid path is within the second gap between the third inlet and the third outlet; and
a fourth fluid path is between the fourth inlet and the fourth outlet and between the second plate and the third circuit board.

4. The electronics package of claim 3, wherein:
the first circuit board is a magnetics circuit board comprising planar windings and a plurality of magnetic cores;
the second circuit board is a power circuit board comprising a plurality of embedded power electronic devices; and
the third circuit board is a control circuit board comprising electronic devices capable of controlling the plurality of embedded power electronic devices.

5. The electronics package of claim 4, wherein the magnetics circuit board is coupled to the power circuit board by connectors and the control circuit board is coupled to the power circuit board by the connectors.

6. The electronics package of claim 4, further comprising at least one capacitor disposed on the power circuit board within the first gap.

7. The electronics package of claim 4, wherein the second gap is smaller than the first gap.

8. The electronics package of claim 4, wherein the magnetics circuit board, the power circuit board, and the control circuit board define a composite DC-DC converter.

9. The electronics package of claim 4, wherein one or more surfaces of the power circuit board have a heat transfer pattern.

10. The electronics package of claim 4, further comprising a plurality of fins extending from one or more surfaces of the power circuit board.

11. The electronics package of claim 1, wherein:
an interior perimeter of the manifold housing comprises a plurality of interlaced ledges comprising a first plurality of ledges and a second plurality of ledges;
a perimeter of the third circuit board and a perimeter of the second circuit board each comprise a plurality of flanges;
the plurality of flanges of the second circuit board is coupled to the first plurality of ledges; and
the plurality of flanges of the third circuit board is coupled to the second plurality of ledges.

12. A composite DC-DC converter comprising:
a manifold housing defining an enclosure and comprising:
an inlet port fluidly coupled to an inlet manifold;
an outlet port fluidly coupled to an outlet manifold;
a magnetics inlet, a first power inlet, a second power inlet, and a control inlet, each fluidly coupled to the inlet manifold and the enclosure; and
a magnetics outlet, a first power outlet, a second power outlet, and a control outlet, each fluidly coupled to the outlet manifold and the enclosure;
a magnetics circuit board coupled to the manifold housing and comprising planar windings and a plurality of magnetic cores;
a power circuit board coupled to the manifold housing such that the power circuit board is offset from the magnetics circuit board by a first gap, the power circuit board comprising a plurality of embedded power electronic devices;
a control circuit board coupled to the manifold housing such that the control circuit board is offset from the power circuit board by a second gap, the control circuit board comprising electronic devices capable of controlling the plurality of embedded power electronic devices;
a first plate coupled to a first surface of the manifold housing; and
a second plate coupled to a second surface of the manifold housing.

13. The composite DC-DC converter of claim 12, further comprising a first gasket disposed between the first plate and the magnetics circuit board and a second gasket disposed between the second plate and the control circuit board, wherein each of the first gasket and the second gasket comprises an individual gasket opening at the magnetics inlet, the first power inlet, the second power inlet, the control inlet, the magnetics outlet, the first power outlet, the second power outlet, and the control outlet.

14. The composite DC-DC converter of claim 12, wherein:
a magnetics fluid path is between the magnetics inlet and the magnetics outlet and the first plate and the control circuit board;
a first power fluid path is within the first gap between the first power inlet and the second power outlet;
a second power fluid path is within the second gap between the second power inlet and the second power outlet; and
a control fluid path is between the control inlet and the control outlet and between the second plate and the control circuit board.

15. The composite DC-DC converter of claim 14, wherein the second gap is smaller than the first gap.

16. The composite DC-DC converter of claim 12, wherein the magnetics circuit board is coupled to the power circuit board by connectors and the control circuit board is coupled to the power circuit board by the connectors.

17. The composite DC-DC converter of claim 12, further comprising at least one capacitor disposed on the power circuit board within the first gap.

18. The composite DC-DC converter of claim 12, wherein one or more surfaces of the power circuit board have a heat transfer pattern.

19. The composite DC-DC converter of claim 12, further comprising a plurality of fins extending from one or more surfaces of the power circuit board.

20. The composite DC-DC converter of claim 12, wherein:
an interior perimeter of the manifold housing comprises a plurality of interlaced ledges comprising a first plurality of ledges and a second plurality of ledges;
a perimeter of the control circuit board and a perimeter of the power circuit board each comprise a plurality of flanges;
the plurality of flanges of the power circuit board is coupled to the first plurality of ledges; and
the plurality of flanges of the control circuit board is coupled to the second plurality of ledges.
